(19) United States
(12) Patent Application Publication
(10) Pub. No.: US 2024/0306370 A1
(43) Pub. Date: Sep. 12, 2024

(54) SEMICONDUCTOR MEMORY DEVICE AND METHOD FOR FABRICATING THE SAME

(71) Applicant: SAMSUNG ELECTRONICS CO., LTD., Suwon-si (KR)

(72) Inventors: Sungnam LYU, Suwon-si (KR); Hyo Jung NOH, Suwon-si (KR); Byoung Hoon LEE, Suwon-si (KR); Jang Eun LEE, Suwon-si (KR); Eul Ji JEONG, Suwon-si (KR)

(21) Appl. No.: 18/537,912

(22) Filed: Dec. 13, 2023

(30) Foreign Application Priority Data
Mar. 6, 2023 (KR) 10-2023-0028945

(51) Int. Cl. H10B 12/00

(52) U.S. Cl. CPC H10B 12/34; H10B 12/053; H10B 12/315

(57) ABSTRACT

A semiconductor memory device includes a substrate having an element separation film defining active areas; and gate structures in trenches on the substrate and intersecting the active areas, wherein each of the gate structures includes a gate insulating layer extending along sidewalls and a bottom surface of a corresponding one of the trenches, a gate electrode layer on the gate insulating layer and including a first metal layer and a second metal layer on the first metal layer, a liner film between the gate insulating layer and the first metal layer and including a same metal material as the first and second metal layers, and a capping film in contact with the second metal layer.

### CROSS-REFERENCE TO RELATED APPLICATION

This application claims priority from Korean Patent Application No. 10-2023-0028945, filed on Mar. 6, 2023, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor memory device and a method for fabricating the same.

### 2. Description of the Related Art

As semiconductor elements are increasingly highly integrated, discrete circuit patterns are becoming more miniaturized to implement more semiconductor elements on the same area. That is, as the degree of integration of the semiconductor element increases, a design rule for the components of the semiconductor element is decreasing. In a highly scaled semiconductor element, a process of forming a plurality of wiring lines and a plurality of buried contacts BC interposed therebetween becomes increasingly complex and difficult.

### SUMMARY

According to an aspect of the present disclosure, there is provided a semiconductor memory device including a substrate including an element separation film defining active areas; and gate structures formed in a trench on the substrate and intersecting the active areas, wherein each of the gate structures includes: a gate insulating layer extending along sidewalls and a bottom surface of the trench, a gate electrode layer disposed on the gate insulating layer to fill the inside of the trench and including a first metal layer and a second metal layer on the first metal layer, a liner film disposed between the gate insulating layer and the first metal layer and including the same metal material as the first and second metal layers, and a capping film in contact with the second metal layer.

According to another aspect of the present disclosure, there is provided a semiconductor memory device including a substrate including an element separation film defining active areas; and gate structures formed in a trench on the substrate and intersecting the active areas, wherein each of the gate structures includes: a gate insulating layer extending along sidewalls and a bottom surface of the trench, a gate electrode layer disposed on the gate insulating layer to fill the inside of the trench and including a first metal layer and a second metal layer on the first metal layer, a work function adjusting film disposed between the gate insulating layer and the gate electrode layer, and a capping film in contact with the second metal layer, the second metal layer is in contact with an upper surface of the work function adjusting film and an upper surface of the first metal layer, respectively, and a step is formed between the upper surface of the work function adjusting film and the upper surface of the first metal layer.

According to another aspect of the present disclosure, there is provided a semiconductor memory device including a substrate including an element separation film defining active areas; a first and second source/drain region disposed within the active areas; bit line structures disposed on the substrate and connected to the first source/drain area; information storage portions disposed on the substrate and connected to the second source/drain area; and gate structures formed in a trench on the substrate and intersecting the active areas, wherein each of the gate structures includes: a gate insulating layer extending along sidewalls and a bottom surface of the trench, a gate electrode layer disposed on the gate insulating layer and including a first metal layer and a second metal layer on the first metal layer, a liner film disposed between the gate insulating layer and the gate electrode layer and including the same metal material as the first and second metal layers, and a capping film in contact with the second metal layer, and the second metal layer covers an upper surface of the liner film.

According to another aspect of the present disclosure, there is provided a method for fabricating a semiconductor memory device, the method including forming an element separation film defining active areas on a substrate; forming a first trench intersecting the active areas in the substrate; sequentially forming a gate insulating layer and a pre liner film along sidewalls and a bottom surface of the first trench; forming a first pre metal layer filling an inside of the first trench on the pre liner film; forming a second trench by removing portions of the first pre metal layer and the pre liner film; forming a second pre metal layer filling a lower portion of the second trench and covering an upper surface of the pre liner film; and forming first and second metal layers and a liner film by performing heat treatment on the first and second pre metal layers and the pre liner film.

### BRIEF DESCRIPTION OF THE DRAWINGS

Features will become apparent to those of skill in the art by describing in detail exemplary embodiments with reference to the attached drawings, in which:

FIG. 1 is a schematic layout view of a semiconductor memory device according to some exemplary embodiments;

FIG. 2 is a layout illustrating only word lines and active areas of FIG. 1;

FIG. 3 is an exemplary cross-sectional view taken along line A-A of FIG. 1;

FIG. 4 is an exemplary cross-sectional view taken along line B-B of FIG. 1;

FIG. 5 is an exemplary cross-sectional view taken along line C-C of FIG. 1;

FIG. 6 is an exemplary cross-sectional view taken along line D-D of FIG. 1;

FIG. 7 is an enlarged view of portion P of FIG. 6;

FIGS. 8 to 10 are enlarged views of portion P of FIG. 6 according to some exemplary embodiments;

FIGS. 11 to 13 are enlarged views of portion P of FIG. 6 according to some exemplary embodiments;

FIG. 14 is a view for describing a semiconductor memory device according to some exemplary embodiments; and

FIGS. 15 to 20 are intermediate step views of stages in a method for fabricating a semiconductor memory device according to some exemplary embodiments.

### DETAILED DESCRIPTION

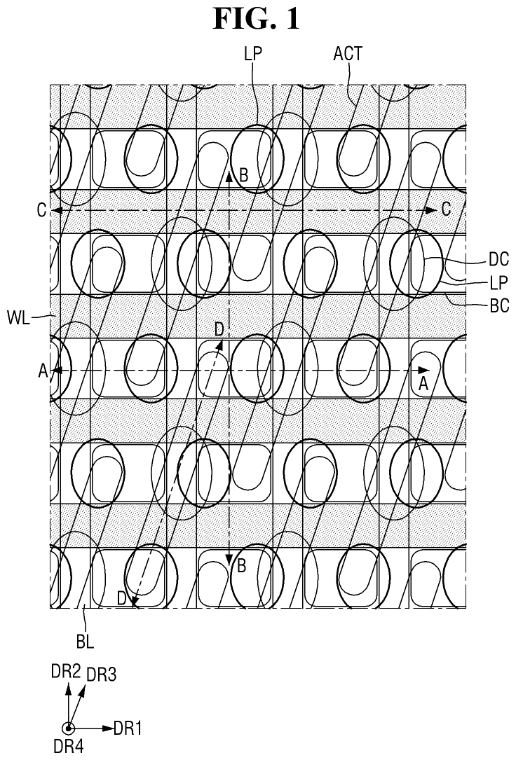

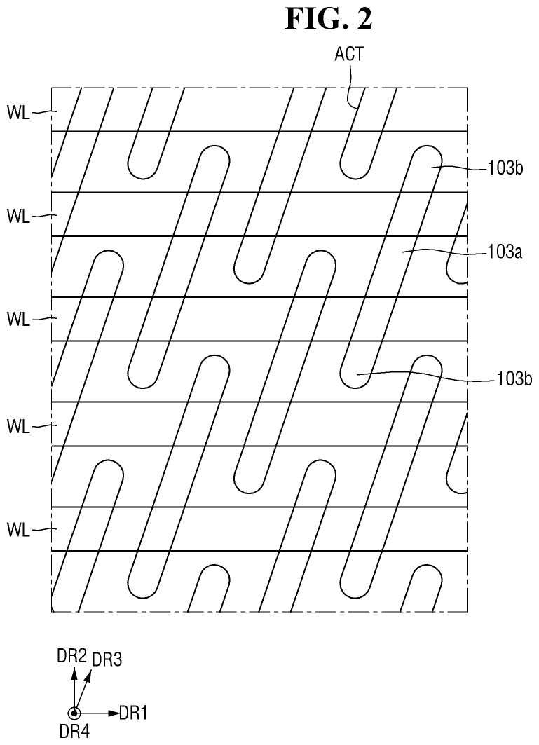

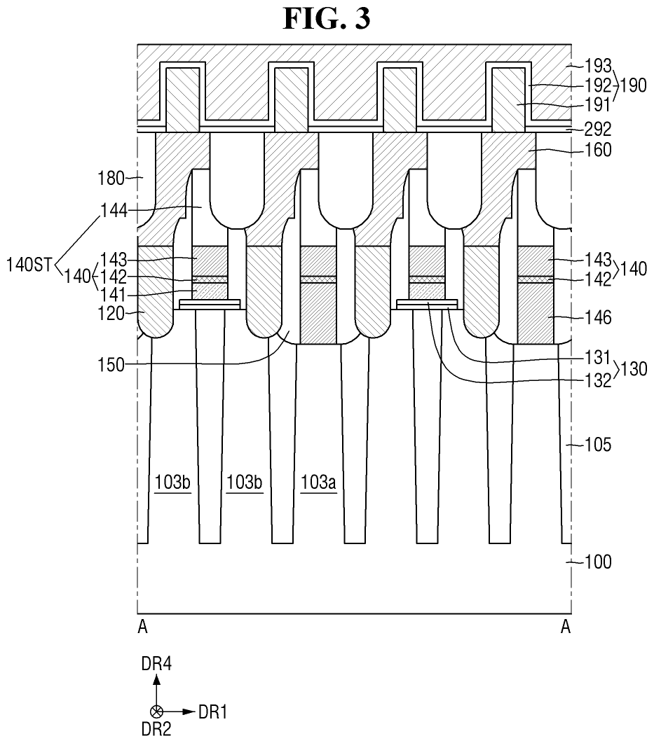

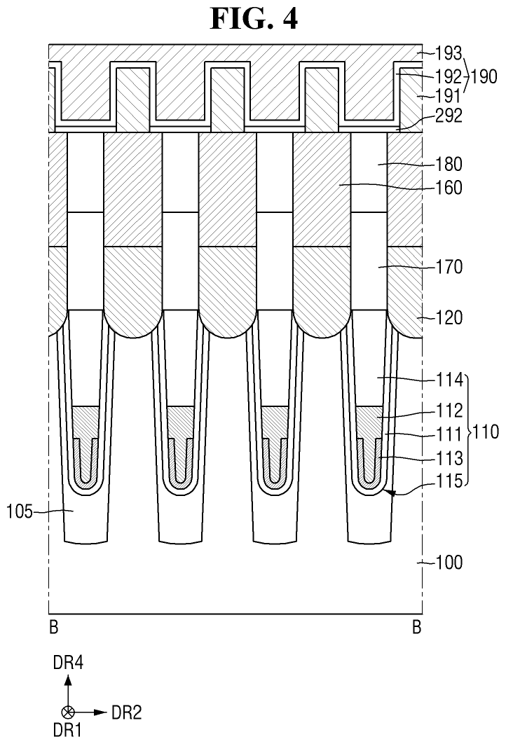

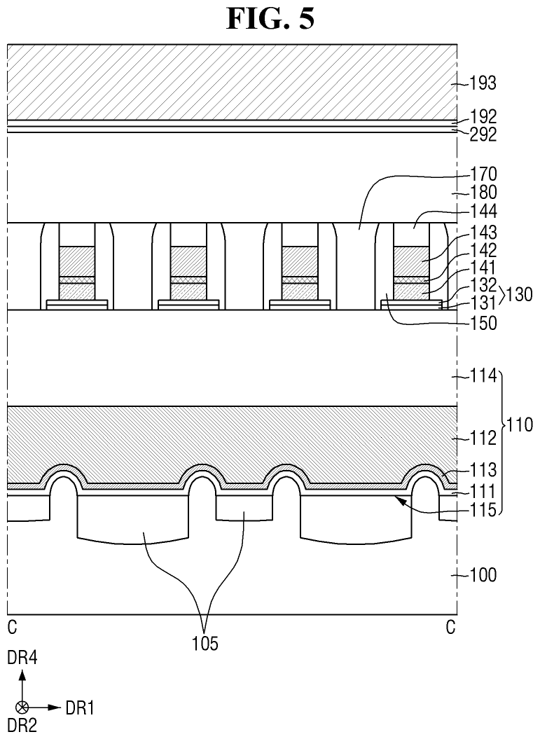

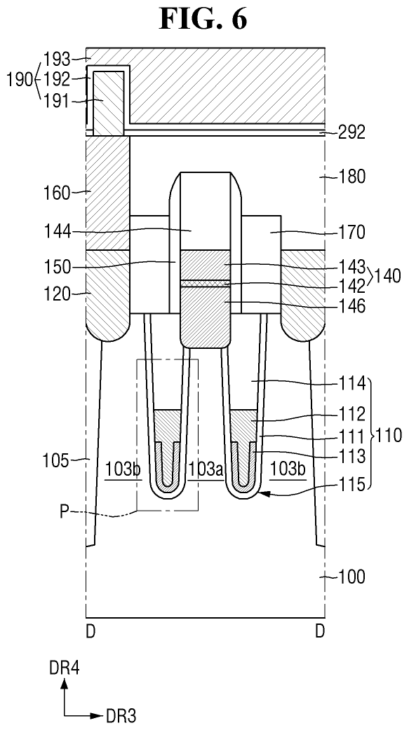

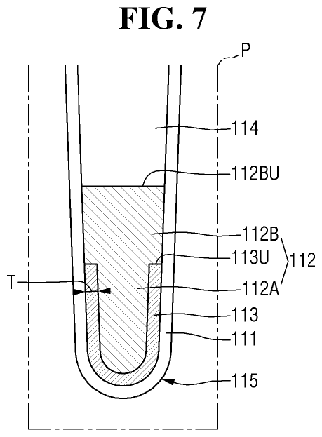

FIG. 1 is a schematic layout view of a semiconductor memory device according to some exemplary embodiments. FIG. 2 is a layout illustrating an arrangement of only word lines and active areas of FIG. 1. FIG. 3 is an exemplary cross-sectional view taken along line A-A of FIG. 1. FIG. 4 is an exemplary cross-sectional view taken along line B-B of FIG. 1. FIG. 5 is an exemplary cross-sectional view taken along line C-C of FIG. 1. FIG. 6 is an exemplary cross-sectional view taken along line D-D of FIG. 1. FIG. 7 is an enlarged view of portion P of FIG. 6.

In the drawings of a semiconductor memory device according to some exemplary embodiments, a dynamic random access memory (DRAM) is illustrated, but embodiments may be implemented in any suitable memory device.

Referring to FIGS. 1 and 2, the semiconductor memory device according to some exemplary embodiments may include a plurality of active areas ACT.

The cell active area ACT may be defined by a cell element separation film 105 formed in a substrate 100 (FIG. 3). As a design rule of the semiconductor memory device is reduced, the cell active area ACT may be disposed in a bar shape of a diagonal line or an oblique line as illustrated. For example, the cell active area ACT may extend in a third direction DR3.

A plurality of gate electrodes extending in the first direction DR1 across the cell active area ACT may be disposed. The plurality of gate electrodes may extend to be parallel to each other. The plurality of gate electrodes may be, e.g., a plurality of word lines WL. The word lines WL may be disposed at equal intervals. A width of the word lines WL or an interval between the word lines WL may be determined depending on a design rule.

Each cell active area ACT may be divided into three portions by two word lines WL extending in the first direction DR1. The cell active area ACT may include a storage connection portion 103b and a bit line connection portion 103a. The bit line connection portion 103a may be positioned at a central portion of the cell active area ACT, and the storage connection portion 103b may be positioned at an end portion of the cell active area ACT.

For example, the bit line connection portion 103a may be an area connected to a bit line BL, and the storage connection portion 103b may be an area connected to an information storage portion 190 (FIG. 3). In other words, the bit line connection portion 103a may correspond to a common drain area, and the storage connection portion 103b may correspond to a source area. Each word line WL and the bit line connection portion 103a and the storage connection portion 103b adjacent thereto may constitute a transistor.

A plurality of bit lines BL extending in a second direction DR2 orthogonal to the word line WL may be disposed on the word line WL. The plurality of bit lines BL may extend to be parallel to each other. The bit lines BL may be disposed at equal intervals. A width of the bit lines BL or an interval between the bit lines BL may be determined depending on a design rule.

A fourth direction DR4 may be orthogonal to the first direction DR1, the second direction DR2, and the third direction DR3. The fourth direction DR4 may be a thickness direction of the substrate 100.

The semiconductor memory device according to some exemplary embodiments may include various contact arrangements formed on the cell active area ACT. The various contact arrangements may include, e.g., a direct contact DC, a buried contact BC, and a landing pad LP.

Here, the direct contact DC may refer to a contact electrically connecting the cell active area ACT to the bit line BL. The buried contact BC may refer to a contact connecting the cell active area ACT to a lower electrode 191 (FIG. 3) of a capacitor. Due to an arrangement structure, a contact area between the buried contact BC and the cell active area ACT may be small. Accordingly, a conductive landing pad LP may be introduced to increase a contact area with the cell active area ACT and increase a contact area with the lower electrode 191 (FIG. 3) of the capacitor.

The landing pad LP may also be disposed between the cell active area ACT and the buried contact BC, and may also be disposed between the buried contact BC and the lower electrode 191 (FIG. 6) of the capacitor. In the semiconductor memory device according to some exemplary embodiments, the landing pad LP may be disposed between the buried contact BC and the lower electrode 191 (FIG. 3) of the capacitor. By increasing the contact area through the introduction of the landing pad LP, contact resistance between the cell active area ACT and the lower electrode of the capacitor may be reduced.

The direct contact DC may be connected to the bit line connection portion 103a. The buried contact BC may be connected to the storage connection portion 103b. As the buried contact BC is disposed at both end portions of the cell active area ACT, the landing pad LP may be disposed adjacent to both ends of the cell active area ACT to partially overlap the buried contact BC. In other words, the buried contact BC may be formed to overlap the cell active area ACT and the cell element separation film 105 (FIGS. 3 and 4) between the word lines WL adjacent to each other and between the bit lines BL adjacent to each other.

The word line WL may be formed in a structure buried in the substrate 100. The word line WL may be disposed across the cell active area ACT between the direct contacts DC or the buried contacts BC. As illustrated, two word lines WL may be disposed across one cell active area ACT. As the cell active area ACT extends in the third direction DR3, the word line WL may have an angle of less than 90 degrees with the cell active area ACT.

The direct contact DC and the buried contact BC may be symmetrically disposed. Accordingly, the direct contact DC and the buried contact BC may be disposed on one straight line in the first direction DR1 and the second direction DR2. Meanwhile, unlike the direct contact DC and the buried contact BC, the landing pad LP may be disposed in a zigzag shape in the second direction DR2 in which the bit line BL extends. In addition, the landing pad LP may be disposed to overlap the same side portion of each bit line BL in the first direction DR1 in which the word line WL extends. For example, each of the landing pads LP of a first line may overlap a left side of a corresponding bit line BL, and each of the landing pads LP of a second line may overlap a right side of a corresponding bit line BL.

Referring to FIGS. 1 to 7, the semiconductor memory device according to some exemplary embodiments may include a plurality of cell gate structures 110, a plurality of bit line structures 140ST, a plurality of bit line contacts 146, and an information storage portion 190.

For example, the substrate 100 may be a silicon substrate or silicon-on-insulator (SOI). In another example, the substrate 100 may include silicon germanium, silicon germanium on insulator (SGOI), indium antimonide, a lead tellurium compound, indium arsenide, indium phosphide, gallium arsenide, or gallium antimonide.

The cell element separation film 105 may be formed in the substrate 100. The cell element separation film 105 may have a shallow trench isolation (STI) structure having excellent element separation characteristics. The cell element separation film 105 may define the cell active area ACT in a memory cell area.

The cell active area ACT defined by the cell element separation film 105 may have a long island shape including a short axis and a long axis, as illustrated in FIGS. 1 and 2. The cell active area ACT may have an oblique shape to have an angle of less than 90 degrees with respect to the word line WL formed in the cell element separation film 105. In addition, the cell active area ACT may have an oblique shape to have an angle of less than 90 degrees with respect to the bit line BL formed on the cell element separation film 105.

The cell element separation film 105 may include, e.g., at least one of a silicon oxide film, a silicon nitride film, and a silicon oxynitride film. The cell element separation film 105 is illustrated as being formed as a single insulating layer, but may also be formed as a plurality of insulating films according to a spaced distance between the cell active areas ACT adjacent to each other.

For example, as illustrated in FIG. 3, an upper surface of the cell element separation film 105 and an upper surface of the substrate 100 may be on the same plane. For example, due to manufacturing processes, a height level of the upper surface of the cell element separation film 105 illustrated in FIG. 3 may be different from a height level of the upper surface of the cell element separation film 105 illustrated in FIG. 4.

The cell gate structure 110 may be formed in the substrate 100 and the cell element separation film 105. The cell gate structure 110 may be formed across the cell element separation film 105 and the cell active area ACT defined by the cell element separation film 105. The cell gate structure 110 may include a cell gate trench 115, a cell gate insulating layer 111, a cell gate electrode 112, a cell gate liner film 113, and a cell gate capping film 114.

Here, the cell gate electrode 112 may correspond to the word line WL. For example, the cell gate electrode 112 may be the word line WL of FIG. 1.

As illustrated in FIG. 5, the cell gate trench 115 (e.g., a plurality of cell gate trenches 115) may be relatively deep in the cell element separation film 105 and may be relatively shallow in the cell active areas ACT. A bottom surface of the word line WL may be curved. That is, a depth of the cell gate trench 115 in the cell element separation film 105 may be greater than a depth of the cell gate trench 115 in the cell active area ACT.

The cell gate insulating layer 111 may extend along sidewalls and a bottom surface of the cell gate trench 115. The cell gate insulating layer 111 may extend along a profile of at least a portion of the cell gate trench 115.

The cell gate insulating layer 111 may include, e.g., at least one of silicon oxide, silicon nitride, silicon oxynitride, or a high-k material having a dielectric constant higher than that of silicon oxide. The high-k material may include, e.g., at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

The cell gate electrode 112 may be disposed on the cell gate insulating layer 111. The cell gate electrode 112 may fill at least a portion in the cell gate trench 115. The cell gate liner film 113 may extend along an upper surface of the cell gate electrode 112.

As illustrated in FIG. 7, the cell gate electrode 112 may include a first metal layer 112A and a second metal layer 112B. The first metal layer 112A may fill a lower area of the cell gate trench 115, and the second metal layer 112B may be disposed on the first metal layer 112A, e.g., so the second metal layer 112B may be between the first metal layer 112A and the cell gate capping film 114.

The cell gate electrode 112 may include at least one of a metal, a metal alloy, and/or conductive metal nitride. The first metal layer 112A and the second metal layer 112B may include, e.g., at least one of Mo, W, TiN, Ru, and/or an alloy thereof.

In some exemplary embodiments, the first metal layer 112A and the second metal layer 112B may include the same metal material. However, as will be described later, in some other exemplary embodiments, the first metal layer 112A and the second metal layer 112B may include different metal materials.

In some exemplary embodiments, a boundary between the first metal layer 112A and the second metal layer 112B is illustrated as not being distinguished, but is not limited thereto. As will be described later, in some other exemplary embodiments, the boundary between the first metal layer 112A and the second metal layer 112B may be distinguished.

The cell gate liner film 113 may be disposed on the first metal layer 112A, e.g., so the cell gate liner film 113 may separate between the first metal layer 112A and the cell gate insulating layer 111. The second metal layer 112B may cover an upper surface of the cell gate liner film 113, e.g., so the second metal layer 112B may directly contact the cell gate insulating layer 111. In some exemplary embodiments, the cell gate liner film 113 may be referred to as a work function adjusting film. For example, a work function of the cell gate liner film 113 may be smaller than a work function of each of the first and second metal layers 112A and 112B.

Referring to FIG. 7, the first metal layer 112A may be in contact (e.g., direct contact) with an inner side surface of the cell gate liner film 113, and the second metal layer 112B may be in contact (e.g., direct contact) with an upper surface 113U of the cell gate liner film 113. Based on the fourth direction DR4, an upper surface 112BU of the second metal layer 112B may be positioned at a higher level than the upper surface 113U of the cell gate liner film 113, e.g., relative to a bottom of the substrate 100.

Based on the fourth direction DR4, a height of the upper surface 113U of the cell gate liner film 113 may be substantially the same as that of the upper surface of the first metal layer 112A. However, as will be described later, in some other exemplary embodiments, the height of the upper surface 113U of the cell gate liner film 113 may be different from the height of the upper surface of the first metal layer 112A.

For example, the cell gate liner film 113 formed on the cell gate insulating layer 111 may have a thickness T of 1 angstroms to 50 angstroms. For example, as illustrated in FIG. 7, the cell gate liner film 113 may have a constant thickness.

The cell gate liner film 113 may overlap the cell gate electrode 112 in the fourth direction DR4. Both sidewalls of the cell gate liner film 113 may be in contact (e.g., direct contact) with the cell gate insulating layer 111.

The cell gate liner film 113 may include any one of metal oxide, a metal, and/or metal nitride. For example, the cell gate liner film 113 may include any one of LaO, ScO, AlO, MgO, HfO₂, Y₂O₃, Ta, TaN, and/or TiSiN.

In addition, the cell gate liner film 113 may include a compound of any one of metal oxide, a metal, and/or a metal nitride, and a metal material included in the first metal layer 112A and/or the second metal layer 112B. For example, the cell gate liner film 113 may include a compound of any one of LaO, ScO, AlO, MgO, HfO₂, Y₂O₃, Ta, TaN, and/or TiSiN, and at least one of Mo, W, TiN, and/or Ru. Through a heat treatment process to be described later, the cell gate liner film 113 may include the same metal material as the metal material of the first metal layer 112A and/or the second metal layer 112B.

The cell gate capping film 114 may be disposed on the cell gate electrode 112 and the cell gate liner film 113. The cell gate capping film 114 may fill the cell gate trench 115 remaining after the cell gate electrode 112 and the cell gate liner film 113 are formed. For example, the cell gate insulating layer 111 may extend along sidewalls of the cell gate capping film 114, e.g., the cell gate insulating layer 111 may directly contact sidewalls of the cell gate capping film 114.

For example, the cell gate capping film 114 may include, e.g., at least one of silicon nitride (SiN), silicon oxynitride (SiON), silicon oxide (SiO₂), silicon carbonitride (SiCN), silicon oxycarbonitride (SiOCN), and a combination thereof. In another example, the cell gate capping film 114 may also include, e.g., polysilicon. For example, as illustrated in FIG. 4, an upper surface of the cell gate capping film 114 may be on the same plane as the upper surface of the cell element separation film 105.

As illustrated in FIG. 5, an impurity doped region may be formed on at least one side of the cell gate structure 110. The impurity doped region may be a source/drain region of a transistor. The impurity doped region may be formed in the storage connection portion 103b and the bit line connection portion 103a of FIG. 2, respectively.

In FIG. 2, when the transistor including each word line WL and the bit line connection portion 103a and the storage connection portion 103b adjacent thereto is an n-channel metal oxide semiconductor (NMOS), the storage connection portion 103b and the bit line connection portion 103a may include at least one of doped n-type impurities, e.g., phosphorus (P), arsenic (As), antimony (Sb), and bismuth (Bi). When the transistor including each word line WL and the bit line connection portion 103a and the storage connection portion 103b adjacent thereto is a p-channel metal oxide semiconductor (PMOS), the storage connection portion 103b and the bit line connection portion 103a may include doped p-type impurities, e.g., boron (B)

The bit line structure 140ST may include a cell conductive line 140, a cell line capping film 144, and a bit line spacer 150.

The cell conductive line 140 may be disposed on the substrate 100 in which the cell gate structure 110 is formed and the cell element separation film 105. The cell conductive line 140 may intersect the cell element separation film 105 and the cell active area ACT defined by the cell element separation film 105. The cell conductive line 140 may be formed to intersect the cell gate structure 110. Here, the cell conductive line 140 may correspond to the bit line BL. For example, the cell conductive line 140 may be the bit line BL of FIG. 1.

The cell conductive line 140 may include, e.g., at least one of a semiconductor material doped with impurities, a conductive silicide compound, conductive metal nitride, a two-dimensional (2D) material, a metal, and a metal alloy. In the semiconductor memory device according to some exemplary embodiments, the 2D material may be a metallic material and/or a semiconductor material. The 2D material may include a two-dimensional allotrope or a two-dimensional compound, and may include, e.g., at least one of graphene, molybdenum disulfide (MoS₂), molybdenum diselenide (MoSe₂), tungsten diselenide (WSe₂), and tungsten disulfide (WS₂). The cell conductive line 140 is illustrated as a single film, but it may include a plurality of conductive films in which a conductive material is stacked.

The cell line capping film 144 may be disposed on the cell conductive line 140. The cell line capping film 144 may extend in the second direction DR2 along the upper surface of the cell conductive line 140. The cell line capping film 144 may include, e.g., at least one of silicon nitride, silicon oxynitride, silicon carbonitride, and silicon oxycarbonitride.

In the semiconductor memory device according to some exemplary embodiments, the cell line capping film 144 may include a silicon nitride film. The cell line capping film 144 is illustrated as a single film, but may include a plurality of films.

The bit line spacer 150 may be disposed on sidewalls of the cell conductive line 140 and the cell line capping film 144. The bit line spacer 150 may extend, e.g., lengthwise, to be long in the second direction DR2.

The bit line spacer 150 is illustrated as a single film, but may have a multilayer film structure. The bit line spacer 150 may include, e.g., one of a silicon oxide layer, a silicon nitride layer, a silicon oxynitride layer (SiON), a silicon oxycarbonitride layer (SiOCN), air, and a combination thereof.

The cell insulating film 130 may be formed on the substrate 100 and the cell element separation film 105. In detail, the cell insulating film 130 may be formed on a portion of the substrate 100 (on which a bit line contact 146 and a storage contact 120 are not formed) and of the upper surface of the cell element separation film 105. The cell insulating film 130 may be disposed between the substrate 100 and the cell conductive line 140 and between the cell element separation film 105 and the cell conductive line 140.

The cell insulating film 130 may be a single film, but may also be a multilayer film including a first cell insulating film 131 and a second cell insulating film 132. For example, the first cell insulating film 131 may include a silicon oxide film, and the second cell insulating film 132 may include a silicon nitride film. For example, the cell insulating film 130 may be a triple film including a silicon oxide film, a silicon nitride film, and a silicon oxide film.

The bit line contact 146 may be formed between the cell conductive line 140 and the substrate 100. The cell conductive line 140 may be disposed on the bit line contact 146.

The bit line contact 146 may be formed between the bit line connection portion 103a of the cell active area ACT and the cell conductive line 140. The bit line contact 146 may electrically connect the cell conductive line 140 and the substrate 100 to each other. The bit line contact 146 may be connected to the bit line connection portion 103a.

The bit line contact 146 may include an upper surface connected to the cell conductive line 140. For example, a width of the bit line contact 146 in the first direction DR1 may be constant as a distance from the upper surface of the bit line contact 146 increases.

The bit line contact 146 may correspond to the direct contact DC. The bit line contact 146 may include, e.g., at least one of a semiconductor material doped with impurities, conductive metal silicide, conductive metal nitride, conductive metal oxide, a metal, and a metal alloy.

In the portion of the cell conductive line 140 on which the bit line contact 146 is formed, the bit line spacer 150 may be formed on the substrate 100 and the cell element separation film 105. The bit line spacer 150 may be disposed on sidewalls of the cell conductive line 140, the cell line capping film 144, and the bit line contact 146.

In the remaining portion of the cell conductive line 140 on which the bit line contact 146 is not formed, the bit line spacer 150 may be disposed on the cell insulating film 130. The bit line spacer 150 may be disposed on the sidewalls of the cell conductive line 140 and the cell line capping film 144.

A fence pattern 170 may be disposed on the substrate 100 and the cell element separation film 105. The fence pattern 170 may be formed to overlap the cell gate structure 110 formed in the substrate 100 and the cell element separation film 105.

The fence pattern 170 may be disposed between the bit line structures 140ST extending in the second direction DR2. The fence pattern 170 may include, e.g., at least one of silicon oxide, silicon nitride, silicon oxynitride, and a combination thereof.

The storage contact 120 may be disposed between the cell conductive lines 140 adjacent to each other in the first direction DR1. The storage contact 120 may be disposed on both sides of the cell conductive line 140. More specifically, the storage contact 120 may be disposed between the bit line structures 140ST. The storage contact 120 may be disposed between the fence patterns 170 adjacent to each other in the second direction DR2.

The storage contact 120 may overlap the substrate 100 and the cell element separation film 105 between the cell conductive lines 140 adjacent to each other. The storage contact 120 may be connected to the cell active area ACT. In detail, the storage contact 120 may be connected to the storage connection portion 103b. Here, the storage contact 120 may correspond to the buried contact BC of FIG. 1.

The storage contact 120 may include, e.g., at least one of a semiconductor material doped with impurities, a conductive silicide compound, conductive metal nitride, and a metal.

A storage pad 160 may be formed on the storage contact 120. The storage pad 160 may be electrically connected to the storage contact 120. The storage pad 160 may be connected to the storage connection portion 103b of the cell active area ACT. Here, the storage pad 160 may correspond to the landing pad LP.

The storage pad 160 may overlap a portion of the upper surface of the bit line structure 140ST. The storage pad 160 may include, e.g., at least one of conductive metal nitride, conductive metal carbide, a metal, and a metal alloy.

A pad separation insulating film 180 may be formed on the storage pad 160 and the bit line structure 140ST. For example, the pad separation insulating film 180 may be disposed on the cell line capping film 144. The pad separation insulating film 180 may define the storage pad 160 forming a plurality of isolation areas. The pad separation insulating film 180 may not cover an upper surface of the storage pad 160. For example, based on the upper surface of the substrate 100, a height of the upper surface of the storage pad 160 may be equal to a height of an upper surface of the pad separation insulating film 180, e.g., the upper surfaces of the storage pad 160 and the pad separation insulating film 180 may be coplanar.

The pad separation insulating film 180 may include an insulating material and may electrically separate the plurality of storage pads 160 from each other. For example, the pad separation insulating film 180 may include, e.g., at least one of a silicon oxide film, a silicon nitride film, a silicon oxynitride film, a silicon oxycarbonitride film, and a silicon carbonitride film.

An etching stop film 292 may be disposed on the upper surface of the storage pad 160 and the upper surface of the pad separation insulating film 180. The etching stop film 292 may include, e.g., at least one of silicon nitride (SiN), silicon carbonitride (SiCN), silicon oxycarbonitride (SiOCN), silicon oxycarbide (SiOC), and silicon boron nitride (SiBN).

The information storage portion 190 may be formed on the storage pad 160. The information storage portion 190 is connected to the storage pad 160. A portion of the information storage portion 190 may be disposed in the etching stop film 292.

The information storage portion 190 may include, e.g., a capacitor. The information storage portion 190 may include a lower electrode 191, a capacitor dielectric film 192, and an upper electrode 193. For example, the upper electrode 193 may be a plate upper electrode having a plate shape.

The lower electrode 191 may be disposed on the storage pad 160. For example, the lower electrode 191 may have a pillar shape.

The capacitor dielectric film 192 may be formed on the lower electrode 191. The capacitor dielectric film 192 may be formed along a profile of the lower electrode 191. The upper electrode 193 may be formed on the capacitor dielectric film 192. The upper electrode 193 may surround an outer sidewall of the lower electrode 191. The upper electrode 193 is illustrated as a single film, but may include a plurality of films.

Each of the lower electrode 191 and the upper electrode 193 may include, e.g., a doped semiconductor material, conductive metal nitride (e.g., titanium nitride, tantalum nitride, niobium nitride, tungsten nitride, or the like), a metal (e.g., ruthenium, iridium, titanium, tantalum, or the like), conductive metal oxide (e.g., iridium oxide, niobium oxide, or the like), and the like.

The capacitor dielectric film 192 may include, e.g., one of silicon oxide, silicon nitride, silicon oxynitride, a high-k material, and a combination thereof. In the semiconductor memory device according to some exemplary embodiments, the capacitor dielectric film 192 may include a stacked film structure in which zirconium oxide, aluminum oxide, and zirconium oxide are sequentially stacked. In the semiconductor memory device according to some exemplary embodiments, the capacitor dielectric film 192 may include a dielectric film including hafnium (Hf). In the semiconductor memory device according to some exemplary embodiments, the capacitor dielectric film 192 may have a stacked film structure of a ferroelectric material film and a paraelectric material film.

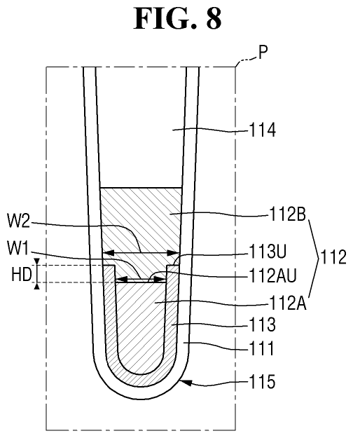

FIGS. 8 to 10 are enlarged views of portion P of FIG. 6 according to some exemplary embodiments. For convenience of explanation, points different from those described with reference to FIGS. 1 to 7 will be mainly described.

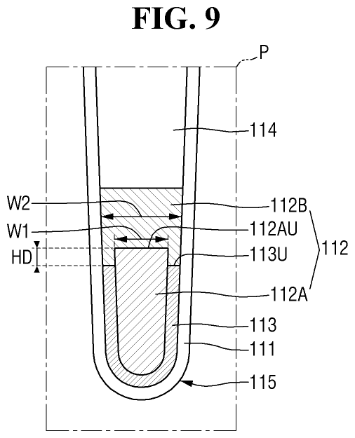

Referring to FIGS. 8 and 9, a stepped structure may be formed between the upper surface of the cell gate liner film 113 and the upper surface of the first metal layer 112A. That is, upper surfaces of the cell gate liner film 113 and the first metal layer 112A may be at different heights (i.e., not coplanar) to define the stepped structure.

Referring to FIG. 8, based on the fourth direction DR4, the upper surface 113U of the cell gate liner film 113 may be positioned at a higher level than an upper surface 112AU of the first metal layer 112A, e.g., relative to the bottom of the substrate 100. The upper surface 113U of the cell gate liner film 113 may protrude more than, e.g., above or beyond, the upper surface 112AU of the first metal layer 112A by a predetermined height HD.

The second metal layer 112B may include a first area in contact with the upper surface 112AU of the first metal layer 112A and with an inner sidewall of the cell gate liner film 113, and a second area above the first area and in contact with the upper surface 113U of the cell gate liner film 113. A first width W1 of the first area may be smaller than a second width W2 of the second area.

Referring to FIG. 9, based on the fourth direction DR4, the upper surface 113U of the cell gate liner film 113 may be positioned at a lower level than the upper surface 112AU of the first metal layer 112A, e.g., relative to the bottom of the substrate 100. The upper surface 112AU of the first metal layer 112A may protrude more than, e.g., above or beyond, the upper surface 113U of the cell gate liner film 113 by a predetermined height HD. For example, the height HD at which the upper surface 112AU of the first metal layer 112A protrudes more than the upper surface 113U of the cell gate liner film 113 may be 200 angstroms or less.

The second metal layer 112B may include a first area in contact, e.g., only, with the upper surface 112AU of the first metal layer 112A, and a second area above and around the first area and in contact with the upper surface 113U of the cell gate liner film 113. A first width W1 of the first area may be smaller than a second width W2 of the second area.

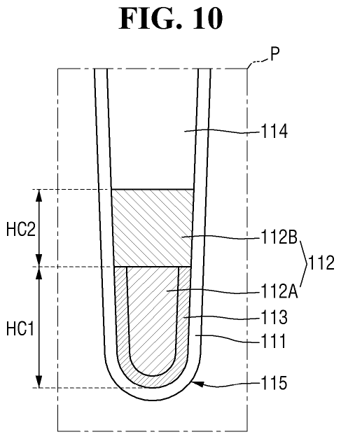

Referring to FIG. 10, the first metal layer 112A and the second metal layer 112B may include different metal materials. For example, the first metal layer 112A and the second metal layer 112B may include different metal materials among Mo, W, TiN, and Ru.

A boundary between the first metal layer 112A and the second metal layer 112B may be distinguished, e.g., visible. For example, even when the first metal layer 112A and the second metal layer 112B include the same material, a difference in grain size or orientation of materials included in the first metal layer 112A and the second metal layer 112B may occur due to heat treatment to be described later. In this case, the first metal layer 112A and the second metal layer 112B may be distinguished (e.g., visibly distinguished) from each other.

Based on the fourth direction DR4, an upper surface of the first metal layer 112A may be positioned on the same level as the upper surface of the cell gate liner film 113. A thickness HC2 of the second metal layer 112B may be equal to a sum HC1 of thicknesses of the cell gate liner film 113 and the first metal layer 112A. For example, the thickness HC2 of the second metal layer may be 1 angstrom to 300 angstroms, and the thickness HC1 of the cell gate liner film 113 and the first metal layer 112A may be 1 angstrom to 300 angstroms.

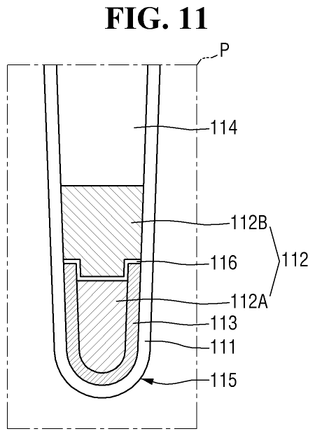

FIGS. 11 to 13 are enlarged views of portion P of FIG. 6 according to some exemplary embodiments. For convenience of explanation, points different from those described with reference to FIGS. 1 to 10 will be mainly described.

In the semiconductor memory device according to some exemplary embodiments, the cell gate structure 110 may further include an oxide film 116. The oxide film 116 may be interposed between the first metal layer 112A and the second metal layer 112B.

The oxide film 116 may be a film formed by oxidizing the materials included in the first metal layer 112A and the cell gate liner film 113. For example, the first metal layer 112A may be formed in a first process chamber, and the second metal layer 112B may be formed in a second process chamber different from the first process chamber. In this case, as processes of forming the first metal layer 112A and the second metal layer 112B are spatially and/or temporally separated from each other, the oxide film 116 may be formed by oxidizing at least a portion of the first metal layer 112A and the cell gate liner film 113 formed previously.

The oxide film 116 may include a first area adjacent to the cell gate liner film 113 and a second area adjacent to the first metal layer 112A. When the materials included in the first metal layer 112A and the cell gate liner film 113 are different from each other, the first area and the second area may include different materials.

Referring to FIG. 11, the oxide film 116 may be formed, e.g., conformally, along the upper surface of the cell gate liner film 113 and the upper surface of the first metal layer 112A. The oxide film 116 may be formed between the cell gate liner film 113 and the second metal layer 112B, and between the first metal layer 112A and the second metal layer 112B.

The oxide film 116 may be formed to have a stepped structure along the upper surface of the cell gate liner film 113 and the upper surface of the first metal layer 112A. A portion of the oxide film 116 in contact with the cell gate liner film 113 may have a higher height than another portion of the oxide film in contact with the first metal layer 112A, e.g., relative to the bottom of the substrate 100.

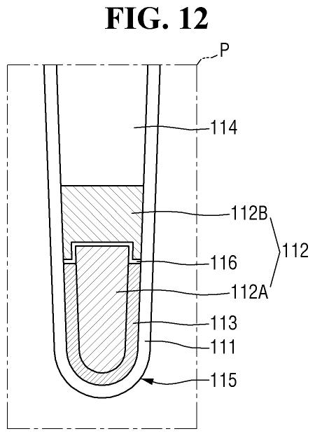

Referring to FIG. 12, the oxide film 116 may be formed to have a stepped structure along the upper surface of the cell gate liner film 113 and the upper surface of the first metal layer 112A. A portion of the oxide film 116 in contact with the cell gate liner film 113 may have a lower height than another portion of the oxide film in contact with the first metal layer 112A, e.g., relative to the bottom of the substrate 100.

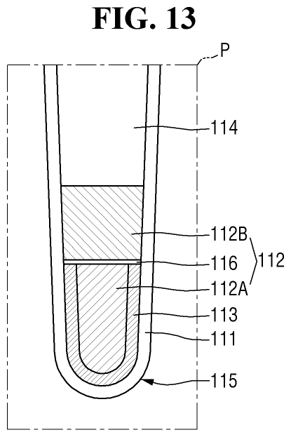

Referring to FIG. 13, the oxide film 116 may substantially not have a stepped structure along the upper surface of the cell gate liner film 113 and the upper surface of the first metal layer 112A. A portion of the oxide film 116 in contact with the cell gate liner film 113 may have substantially the same height as another portion of the oxide film in contact with the first metal layer 112A.

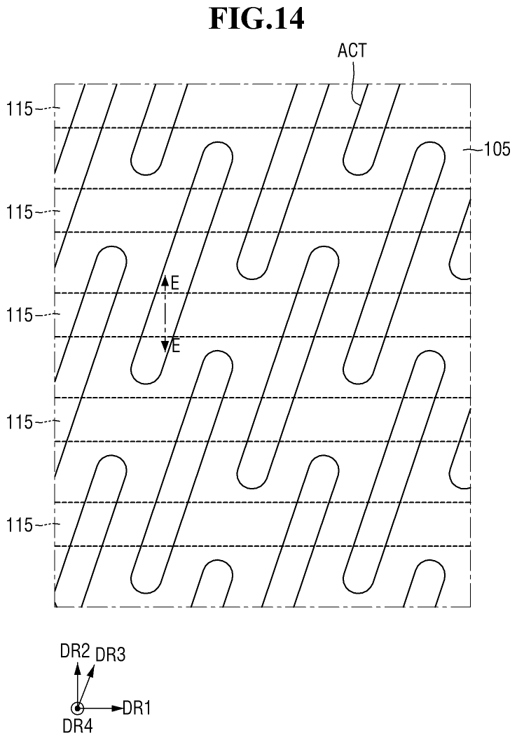

FIGS. 14 to 20 are intermediate step views for describing stages in a method for fabricating a semiconductor memory device according to some exemplary embodiments. For the convenience of explanation, the contents overlapping those described with reference to FIGS. 1 to 7 will be only briefly described or omitted.

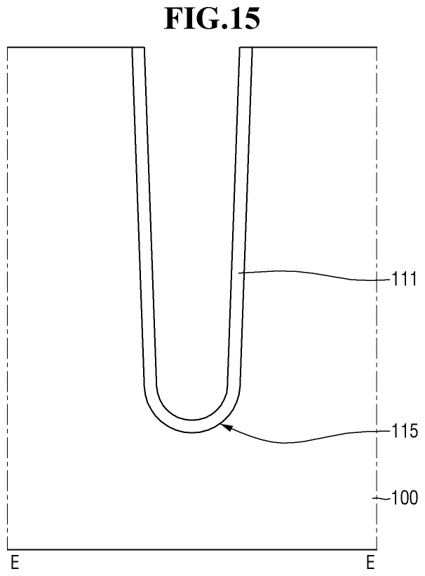

For reference, FIG. 14 is a schematic layout view for describing a method for fabricating a semiconductor memory device according to some exemplary embodiments. FIGS. 15 to 20 are cross-sectional views taken along line E-E of FIG. 14.

Referring to FIG. 14, a cell element separation film 105 may be formed in the substrate 100. The cell element separation film 105 may have a shallow trench isolation (STI) structure having excellent element separation characteristics. The cell element separation film 105 may define the cell active area ACT in a memory cell area.

The cell element separation film 105 may include, e.g., at least one of a silicon oxide film, a silicon nitride film, and a silicon oxynitride film, but is not limited thereto. The cell element separation film 105 is illustrated as being formed as a single insulating layer, but may also be formed as a plurality of insulating films.

Referring to FIGS. 14 and 15, a first trench 115 (will be referred to hereinafter interchangeably with the cell gate trench 115) may be formed in the substrate 100 and the cell element separation film 105. For example, the first trench 115 may be formed by forming a mask pattern on the substrate 100 and then etching the substrate 100 using the mask pattern as an etching mask. The first trench 115 may extend in the first direction DR1. The first trench 115 may be formed across the cell element separation film 105 and the cell active area ACT defined by the cell element separation film 105.

The cell gate insulating layer 111 may be formed on an upper surface of the substrate 100 and the first trench 115. The cell gate insulating layer 111 may be formed using an atomic layer deposition (ALD) process or a chemical vapor deposition (CVD) process. The cell gate insulating layer 111 may be formed, e.g., conformally, on sidewalls and a bottom surface of the first trench 115. The cell gate insulating layer 111 may include silicon oxide.

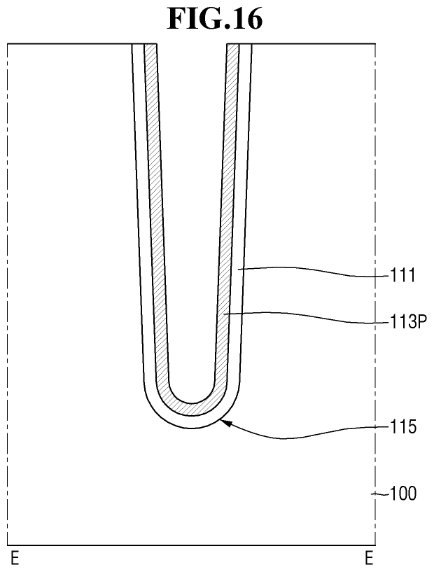

Referring to FIG. 16, a pre cell gate liner film 113P may be formed on the cell gate insulating layer 111. The pre cell gate liner film 113P may be formed, e.g., conformally, along the sidewalls and the bottom surface of the first trench 115 to fill the inside of the first trench 115.

The pre cell gate liner film 113P may include any one of metal oxide, a metal, and/or metal nitride. For example, the pre cell gate liner film 113P may include any of, e.g., LaO, ScO, AlO, MgO, HfO₂, Y₂O₃, Ta, TaN, and/or TiSiN.

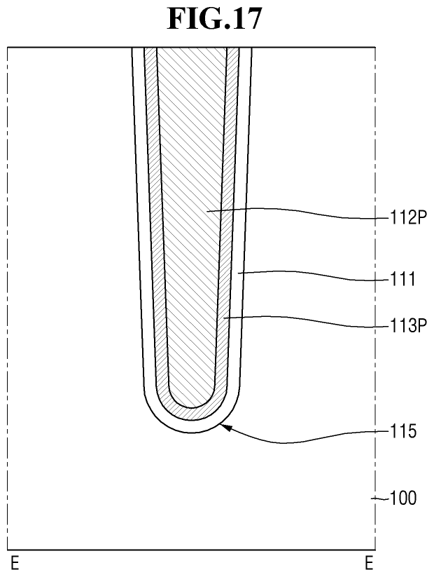

Referring to FIG. 17, a pre cell gate electrode 112P may be formed on the cell gate insulating layer 111. A conductive material may be deposited on the cell gate insulating layer 111. In this case, the conductive material may, e.g., completely, fill the first trench 115.

The deposition of the conductive material may be performed using a chemical vapor deposition (CVD) process or the like. The conductive material may include at least one of, e.g., Mo, W, TiN, and/or Ru.

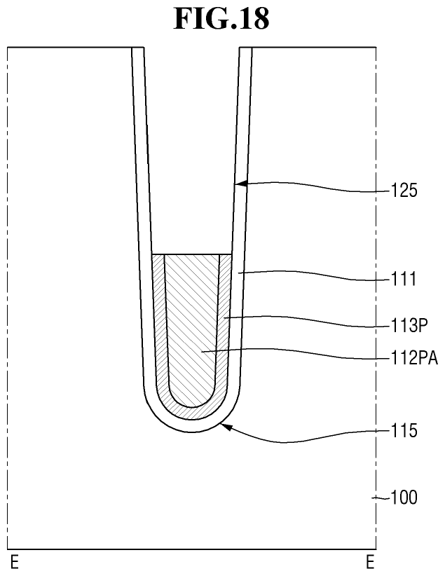

Referring to FIG. 18, a first pre cell gate electrode 112PA may be formed by etching a portion of the pre cell gate electrode 112P and the pre cell gate liner film 113P. For example, the conductive material may be etched through an etch-back process.

The etch-back process may be performed using etch selectivity of a metal material included in the pre cell gate electrode 112P and the pre cell gate liner film 113P and oxide included in the cell gate insulating layer 111. Through the etch-back process, a second trench 125 may be formed on the first pre cell gate electrode 112PA and the pre cell gate liner film 113P.

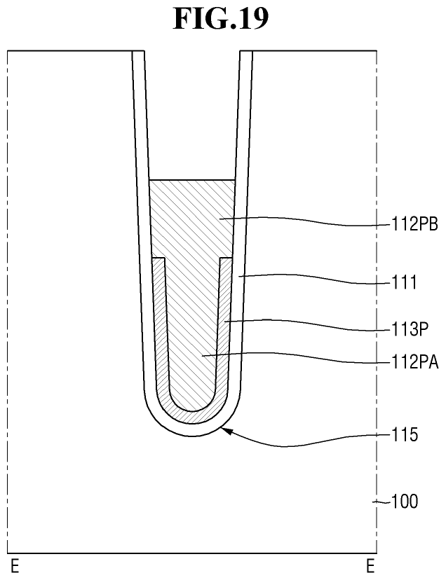

Referring to FIG. 19, a second pre cell gate electrode 112PB filling a portion of the second trench 125 may be formed on the first pre cell gate electrode 112PA and the pre cell gate liner film 113P. The second pre cell gate electrode 112PB may cover an upper surface of the pre cell gate liner film 113P.

A conductive material may be deposited on the first pre cell gate electrode 112PA and the pre cell gate liner film 113P. In this case, the conductive material may fill the second trench 125. The deposition of the conductive material may be performed using a chemical vapor deposition (CVD) process or the like. The conductive material may include at least one of, e.g., Mo, W, TiN, and/or Ru.

In some exemplary embodiments, heat treatment may be performed on the first and second pre cell gate electrodes 112PA and 112PB and the pre cell gate liner film 113P. Accordingly, as a result of the heat treatment, the cell gate liner film 113 of FIG. 7 may include a compound of the material of the pre cell gate liner film 113P (e.g., any of LaO, ScO, AlO, MgO, HfO₂, Y₂O₃, Ta, TaN, and/or TiSiN) and the conductive material of the first and second pre cell gate electrodes 112PA and 112PB (e.g., at least one of Mo, W, TiN, and Ru).

In order to implement low-resistance characteristic of the gate structure of the semiconductor memory device, a metal material, e.g., molybdenum (Mo), may be used. In this case, an energy band gap of the semiconductor memory device may increase due to a high work function of the metal material. In some exemplary embodiments, a liner film capable of adjusting a work function may be formed between the gate insulating layer and the gate electrode while using a metal material having low resistance as a gate electrode. When the liner film according to some exemplary embodiments is coupled to the gate insulating layer, the liner film may adjust the work function by forming a dipole at an interface therebetween. As a result, it is possible to secure low resistance characteristics while lowering the energy band gap of the semiconductor memory device.

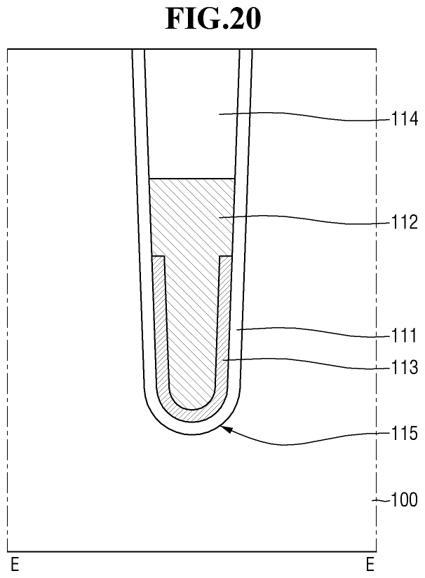

Referring to FIG. 20, the cell gate capping film 114 may be formed on the cell gate liner film 113. The cell gate capping film 114 may be formed on the first trench 115 coated with the cell gate insulating layer 111. For example, the cell gate capping film 114 may be formed by forming a capping film on the entire surface of the substrate 100 and then performing a planarization process or the like. The cell gate capping film 114 may include any of, e.g., a silicon nitride film, a silicon oxide film, and a silicon oxynitride film. In this case, a portion of the cell gate insulating layer 111 covering the upper surface of the substrate 100 may be removed together.

Through the planarization process, the cell gate structure 110 may be formed. The cell gate structure 110 may include the cell gate trench 115, the cell gate insulating layer 111, the cell gate electrode 112, the cell gate liner film 113, and the cell gate capping film 114. The cell gate electrode 112 may correspond to the word line WL.

Subsequently, the bit line structure 140ST extending in the second direction DR2 may be formed on the substrate 100. The bit line structure 140ST may include the cell conductive line 140, the cell line capping film 144, and the bit line spacer 150.

The storage contact 120, the storage pad 160, and the information storage portion 190 may be formed on the storage connection portion 103b of the cell active area ACT. The information storage portion 190 may include the lower electrode 191, the capacitor dielectric film 192, and the upper electrode 193.

By way of summation and review, aspects of the present disclosure provide a semiconductor memory device capable of improving reliability and performance. Aspects of the present disclosure also provide a method for fabricating a semiconductor device capable of improving reliability and performance.

That is, embodiments provide a semiconductor memory device including a liner film in the gate electrode to prevent or to substantially minimize a high flatband voltage due to a high work function (e.g., when Mo having low resistance characteristics is used as a gate electrode). The flatband voltage of the gate structure may be controlled by inserting the liner film, which is capable of forming a dipole between the gate oxide and the gate metal, at a bottom of the gate structure through metal etch back and metal (e.g., Mo) deposition using the selectivity of the metal and oxide. Further, since the metal of the gate electrode is formed in different processes (e.g., as two different metal portions), an oxide layer may be formed at the interface between the two different metal portions.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor memory device, comprising:
a substrate including an element separation film defining active areas; and
gate structures in trenches on the substrate, the gate structures intersecting the active areas, and each of the gate structures including:
a gate insulating layer extending along sidewalls and a bottom surface of a corresponding one of the trenches,
a gate electrode layer on the gate insulating layer, the gate electrode layer including a first metal layer and a second metal layer on the first metal layer,
a liner film between the gate insulating layer and the first metal layer, the liner film including a same metal material as the first metal layer and the second metal layer, and
a capping film in contact with the second metal layer.

2. The semiconductor memory device as claimed in claim 1, wherein the first metal layer is in contact with an inner side surface of the liner film, and the second metal layer is in contact with an upper surface of the liner film.

3. The semiconductor memory device as claimed in claim 1, wherein a height of an upper surface of the second metal layer is higher than a height of an upper surface of the liner film.

4. The semiconductor memory device as claimed in claim 1, wherein a height of an upper surface of the liner film is higher than a height of an upper surface of the first metal layer.

5. The semiconductor memory device as claimed in claim 1, wherein a height of an upper surface of the liner film is lower than a height of an upper surface of the first metal layer.

6. The semiconductor memory device as claimed in claim 1, wherein a sum of thicknesses of the first metal layer and the liner film is equal to a thickness of the second metal layer.

7. The semiconductor memory device as claimed in claim 1, wherein each of the gate structures further includes an oxide film between the first metal layer and the second metal layer.

8. The semiconductor memory device as claimed in claim 7, wherein the oxide film includes a first area adjacent to the liner film and a second area adjacent to the first metal layer, the first area and the second area including different materials.

9. The semiconductor memory device as claimed in claim 1, wherein the first metal layer includes a first metal material, and the second metal layer includes a second metal material.

10. The semiconductor memory device as claimed in claim 9, wherein the liner film includes any of a metal oxide, a metal, and a metal nitride.

11. The semiconductor memory device as claimed in claim 10, wherein the liner film includes:
a compound of any of the metal oxide, the metal, and the metal nitride, and the first metal material, and
a compound of any of the metal oxide, the metal, and the metal nitride, and the second metal material.

12. The semiconductor memory device as claimed in claim 1, further comprising:
first source/drain regions and second source/drain regions within the active areas;
bit line structures on the substrate and connected to the first source/drain regions; and
information storage portions on the substrate and connected to the second source/drain regions.

13. A semiconductor memory device, comprising:
a substrate including an element separation film defining active areas; and
gate structures in trenches on the substrate, respectively, the gate structures intersecting the active areas, and each of the gate structures including:
a gate insulating layer extending along sidewalls and a bottom surface of a corresponding one of the trenches,
a gate electrode layer on the gate insulating layer, the gate electrode layer including a first metal layer and a second metal layer on the first metal layer,
a work function adjusting film between the gate insulating layer and the gate electrode layer, and
a capping film in contact with the second metal layer,
wherein the second metal layer is in contact with an upper surface of the work function adjusting film and an upper surface of the first metal layer, respectively, and
wherein a step is defined between the upper surface of the work function adjusting film and the upper surface of the first metal layer.

14. The semiconductor memory device as claimed in claim 13, wherein the upper surface of the work function adjusting film is positioned at a higher level than the upper surface of the first metal layer.

15. The semiconductor memory device as claimed in claim 13, wherein the upper surface of the first metal layer is positioned at a higher level than the upper surface of the work function adjusting film.

16. The semiconductor memory device as claimed in claim 13, wherein the second metal layer includes a first area in contact with the upper surface of the first metal layer and a second area in contact with the upper surface of the work function adjusting film, a first width of the first area being smaller than a second width of the second area.

17. The semiconductor memory device as claimed in claim 13, wherein each of the first metal layer and the second metal layer includes at least one of Mo, W, TiN, and Ru.

18. The semiconductor memory device as claimed in claim 17, wherein the work function adjusting film includes any of LaO, ScO, AlO, MgO, HfO₂, Y₂O₃, Ta, TaN, and TiSiN.

19. The semiconductor memory device as claimed in claim 18, wherein the work function adjusting film includes a compound of any of the LaO, ScO, AlO, MgO, HfO₂, Y₂O₃, Ta, TaN, and TiSiN, and at least one of the Mo, W, TiN, and Ru.

20. A semiconductor memory device, comprising:
a substrate including an element separation film defining active areas;
first and second source/drain regions within the active areas;
bit line structures on the substrate and connected to the first source/drain regions;
information storage portions on the substrate and connected to the second source/drain region; and
gate structures in trenches on the substrate, respectively, the gate structures intersecting the active areas, and each of the gate structures including:
a gate insulating layer extending along sidewalls and a bottom surface of a corresponding one of the trenches,
a gate electrode layer on the gate insulating layer and including a first metal layer and a second metal layer on the first metal layer,
a liner film between the gate insulating layer and the gate electrode layer, the liner film including a same metal material as the first metal layer and the second metal layer, and the second metal layer covering an upper surface of the liner film, and
a capping film in contact with the second metal layer.

21. (canceled)
